(19) United States
(12) Patent Application Publication
(10) Pub. No.: US 2024/0160113 A1
(43) Pub. Date: May 16, 2024

(54) METHOD FOR OPERATING AN OPTICAL SYSTEM

(71) Applicant: Carl Zeiss SMT GmbH, Oberkochen (DE)

(72) Inventors: Julian Zips, Augsburg (DE); Marwene Nefzi, Aachen (DE)

(21) Appl. No.: 18/419,167

(22) Filed: Jan. 22, 2024

Related U.S. Application Data
(63) Continuation of application No. PCT/EP2022/069662, filed on Jul. 13, 2022.

(30) Foreign Application Priority Data
Aug. 5, 2021 (DE) 10 2021 208 488.5

(51) Int. Cl. G03F 7/00

(52) U.S. Cl. CPC G03F 7/70504; G03F 7/70525; G03F 7/7085; G03F 7/70891

(57) ABSTRACT

A method for operating an optical system comprises the following steps: (a) using sensors to measure values of at least one physical quantity at a plurality of different sensor positions in the optical system; and (b) diagnosing an existing or expected malfunction of the optical system on the basis of this measurement. The values measured in step (a) are used to perform model-based determination of at least one parameter at other positions, none of which correspond to the sensor positions. The diagnosis in step (b) also being carried out on the basis of this model-based determination.

### CROSS-REFERENCE TO RELATED APPLICATIONS

The present application is a continuation of, and claims benefit under 35 USC 120 to, international application PCT/EP2022/069662, filed Jul. 13, 2022, which claims benefit under 35 USC 119 of German Application No. 10 2021 208 488.5, filed Aug. 5, 2021. The entire disclosure of each these applications is incorporated by reference herein.

### FIELD

The disclosure relates to a method for operating an optical system.

### BACKGROUND

Microlithography is used for producing microstructured components, such as for example integrated circuits or LCDs. The microlithography process is conducted in what is called a projection exposure apparatus, which comprises an illumination device and a projection lens. The image of a mask (=reticle) illuminated via the illumination device is projected here via the projection lens onto a substrate (e.g. a silicon wafer) that is coated with a light-sensitive layer (photoresist) and arranged in the image plane of the projection lens, in order to transfer the mask structure onto the light-sensitive coating of the substrate.

In projection lenses designed for the EUV range, i.e. at wavelengths of for example approximately 13 nm or approximately 7 nm, mirrors are used as optical components for the imaging process owing to the general lack of availability of suitable light-transmissive refractive materials.

In a known setup, the projection lens may comprise both a load-transferring support structure in the form of a force frame and, provided independently thereof, a measurement structure in the form of a sensor frame, with both support structure and measurement structure being mechanically linked independently of one another to a base of the optical system via mechanical links that act as a dynamic decoupling mechanism. Thermally induced deformations of the sensor frame may occur on account of thermal influences (which include both the electromagnetic radiation acting during operation and heat dissipation from components such as actuators or heating apparatuses, for example), whereby optical aberrations can ultimately be caused during the operation of the projection exposure apparatus.

In this case, temperature sensors used to establish the thermal state of the optical system or projection lens of the projection exposure apparatus are generally only available in limited number and frequently not available at the respective positions of the components to be monitored in respect of their reliable operation. Together with the complexity present as a result of the optical system composed of different modules, these circumstances have as a consequence that the search for errors and the introduction of suitable countermeasures, for example the replacement or servicing of specific components, are often only introduced with delays (e.g. only once the unscheduled outage of the optical system has occurred), whereby the availability of the projection exposure apparatus can be undesirably restricted.

### SUMMARY

The present disclosure seeks to provide a method for operating an optical system which enables an identification of errors that is as reliable and timely as possible and the planning of suitable countermeasures.

A method according to the disclosure for operating an optical system includes the following steps:
a) measuring, with sensor assistance, values of at least one physical variable at a plurality of different sensor positions within the optical system; and
b) diagnosing an existing or expected malfunction of the optical system on the basis of this measurement;
wherein the values measured in step a) are used to carry out a model-based determination of at least one parameter at further positions, none of which correspond to a sensor position, with the diagnosis in step b) also being made on the basis of this model-based determination.

For example, the disclosure involves realizing the diagnosis of a malfunction (for example with localization of corresponding causes of the error) with increased information density during the operation of an optical system, inasmuch as a suitable model is included in the diagnosis by way of the sensor-assisted measurement of one or more physical variables (such as the temperature, for example) in order to establish a parameter relevant to this diagnosis (e.g. the thermal load) at further positions that are not directly “observable” by way of the sensors present.

As a result, there can be a substantially more reliable and for example more timely identification of errors and appropriate planning of suitable countermeasures on the basis of the method according to the disclosure.

The at least one physical variable measured in step a) can be the temperature for example, but, in addition or as an alternative, further embodiments may also comprise for example the wavefront provided by the optical system in a given plane.

The at least one parameter determined in model-based fashion may comprise the thermal load for example.

According to an embodiment, the aforementioned further positions, none of which correspond to a sensor position, are in each case situated at a component of the optical system to be monitored in respect of its operation.

According to an embodiment, the model-based determination of at least one parameter at further positions, none of which correspond to a sensor position, is used to plan a countermeasure for remedying or avoiding the malfunction. For example, there may in the process also be a warning or the like, this optionally also possibly containing an indication of a component presumed to be faulty.

According to an embodiment, this planning is additionally implemented on the basis of an assessment of the relevance of the malfunction. For example, what can be taken into account here is whether an upcoming outage of a component e.g. does not justify shutting down the entire optical system, with the result that the next servicing pause, planned in any case, can also be used in this case for a possibly desired replacement of the relevant component.

According to an embodiment, the optical system is a microlithographic optical system, for example a projection lens of a microlithographic projection exposure apparatus.

According to an embodiment, the sensors are arranged on a sensor frame of the projection exposure apparatus. The further positions, none of which correspond to a sensor position, can be situated for example on a force frame of the projection exposure apparatus.

Further configurations of the disclosure are apparent from the description and the dependent claims.

The disclosure is explained in greater detail below on the basis of exemplary embodiments illustrated in the accompanying figures.

### BRIEF DESCRIPTION OF THE DRAWINGS

In the drawings:

FIG. 1 shows a schematic illustration for explaining an exemplary architecture, in which a method according to the disclosure can be realized;

FIG. 2 shows a diagram for explaining a principle underlying the present disclosure; and

FIG. 3 shows a schematic illustration of the possible structure of a microlithographic projection exposure apparatus designed for operation in the EUV range.

### DETAILED DESCRIPTION

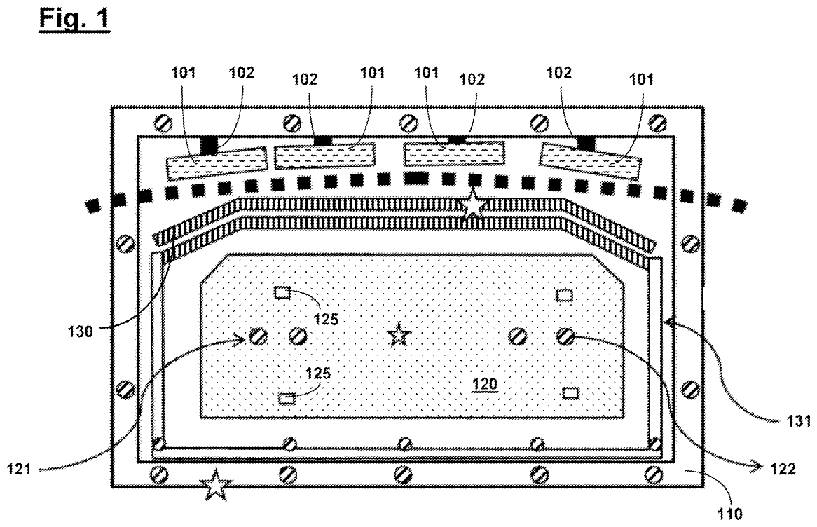

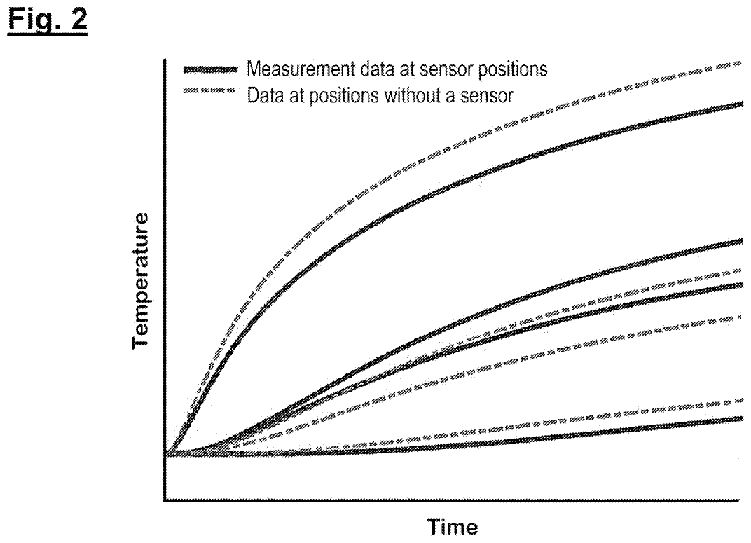

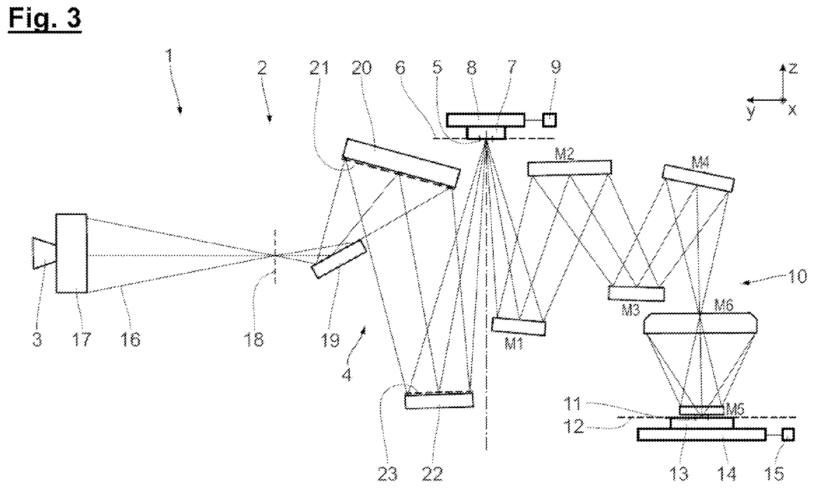

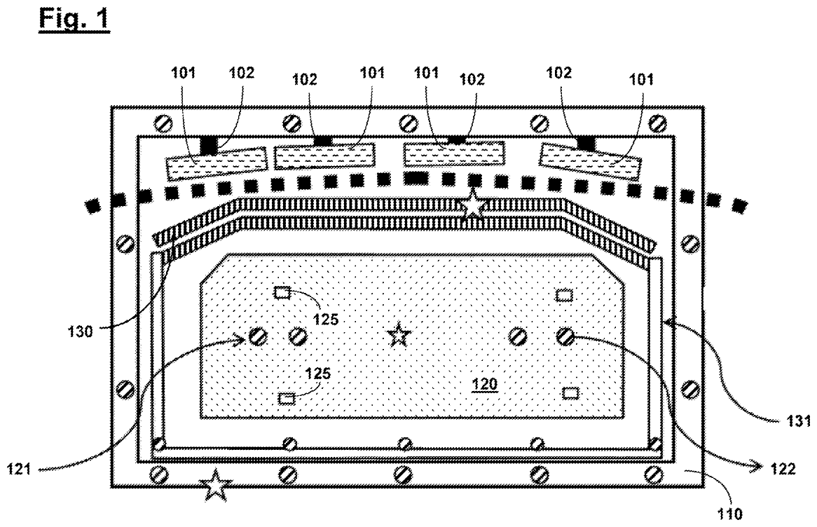

FIG. 1 shows a merely schematic and much simplified illustration of a possible architecture within a microlithographic projection exposure apparatus, in which the method according to the disclosure can be realized.

According to FIG. 1, a plurality of mirrors 101 are in this case assembled on a load-transferring support structure in the form of a force frame 110, wherein “102” denotes actuators for positioning the mirrors 101. Moreover, provision is made of a measurement structure in the form of a sensor frame 120, which is dynamically decoupled from the force frame 110. FIG. 1 also indicates cooling apparatuses 121, 122, depicted by hatching, for the support frame 110, the sensor frame 120 and a heat shield located between the force frame 110 and the sensor frame 120, with a cooling fluid flowing through each cooling apparatus. Specifically, “130” denotes a thermal shield of the optical path and “131” denotes a heat shield through which a cooling fluid flows (e.g. a water-cooled heat shield), located between the force frame 110 and sensor frame 120.

According to the thermal architecture depicted in FIG. 1, a plurality of sensors 125 serve to measure the temperature present at different positions.

The method according to the disclosure can use values (temperature values in this example) measured with sensor assistance to calculate a relevant parameter (the heat flux in this example) at other positions, none of which correspond to a sensor position, in model-based fashion and the relevant parameter can form the basis for a diagnosis of an existing or expected malfunction of the optical system. In the specific example of FIG. 1, the respective heat flux for example can be calculated in, for instance, the region of the actuators 102 in model-based fashion, with the result that a possibly existing or imminent malfunction of the actuators 102 can be diagnosed without having to resort to temperature sensors in the region of the actuators 102, as these are not present there in the setup according to FIG. 1. Using the model- and measurement-based method according to the disclosure, it is also possible to draw conclusions about other thermal loads, for example heating apparatuses or parasitic loads of electrical supply lines or cables, or else interface loads to the remaining part of the optical system (e.g. the projection exposure apparatus).

As a result, according to the disclosure a substantially increased information density—in comparison with exclusive use of the values measured on the basis of the temperature—is provided in model-based fashion, whereby an identification of errors and the introduction of appropriately suitable countermeasures can in turn be implemented with greater reliability and, for example, also in substantially more timely fashion.

FIG. 2 shows, once again merely by way of example, a diagram with exemplary time-dependent temperature curves at different positions in the optical system, wherein the respective solid curves correspond to the measurement data captured at different sensor positions. By contrast, the dashed curves in FIG. 2 correspond to data which, as described above, were calculated in model-based fashion at further positions (none of which correspond to a sensor position). In this context, attention should be drawn to the fact that the diagram in FIG. 2 is purely exemplary, wherein, for example, the number of (dashed) curves or data which were established in model-based fashion for the further positions (none of which correspond to a sensor position) may also substantially exceed the number of curves measured with sensor assistance.

A relationship between the thermal loads at different locations/positions within the optical system or projection lens and the measured temperatures can be determined in model-based fashion:

T=B·Q (1)

where T[K] denotes the measured temperature at various sensor positions and Q [W] denotes the dissipated heat flux of individual components. B [K/W] denotes a sensitivity matrix which can be determined on the basis of a thermal model for the optical system or projection lens and can be updated with the aid of measurements. In matrix form, equation (1) can be written as:

$$[ \begin{matrix}{T}_{1 t 1} & {T}_{2 t 1} & {T}_{3 t 1} & … & {T}_{kt 1} \\ {T}_{1 t 2} & {T}_{2 t 2} & {T}_{3 t 2} & … & {T}_{kt 2} \\ {T}_{1 t 3} & {T}_{2 t} & {T}_{3 t 3} & … & {T}_{kt 3} \\ … & … & … & … & … \\ {T}_{1 t n} & {T}_{2 t n} & {T}_{3 t n} & … & {T}_{ktn}\end{matrix} ] = [ \begin{matrix}{B}_{1 t 1} & {B}_{2 t 1} & {B}_{3 t 1} & … & {B}_{lt 1} \\ {B}_{1 t 2} & {B}_{2 t 2} & {B}_{3 t 2} & … & {B}_{lt 2} \\ {B}_{1 t 3} & {B}_{2 t} & {B}_{3 t 3} & … & {B}_{lt 3} \\ … & … & … & … & … \\ {B}_{1 tn} & {B}_{2 t n} & {B}_{3 t n} & … & {B}_{ltn}\end{matrix} ] \cdot [ \begin{matrix}{Q}_{11} & {Q}_{12} & {Q}_{13} & … & {Q}_{1 m} \\ {Q}_{21} & {Q}_{22} & {Q}_{23} & … & {Q}_{2 m} \\ {Q}_{31} & {Q}_{32} & {Q}_{33} & … & {Q}_{3 m} \\ … & … & … & … & … \\ {Q}_{l 1} & {Q}_{l 2} & {Q}_{l 3} & … & {Q}_{l m}\end{matrix} ] \qquad ( 2 )$$

In this case, the thermal load can be defined in model-based fashion at as many points as desired in the optical system or projection lens. The effects of this thermal load on a specific temperature sensor is determined on the basis of the entries in the sensitivity matrix B.

In the case of a known relationship according to equation (1), it is consequently possible to determine the heat flux at various further positions (none of which corresponds to a sensor position) in the optical system in model-based fashion and on the basis of sensor-based temperature measurements, in order to locate a possibly present thermal overload.

Moreover, measurements of further physical variables (e.g. a measurement of the voltage or electric current) can optionally be used to determine a change in the actuator power. In turn, this information can be used to determine whether a thermal overload present has its origin in one or more of the actuators or at other positions of the optical system with a high probability.

In further embodiments, optical aberrations also measured with sensor assistance can additionally be used to establish the origin of a thermal overload. Thermal effects leave a specific signature of the overlay error, which can be used to locate thermal overloads in the optical system or projection lens. In a manner similar to equation (1), the following relationship can be specified:

$$LoS = T \cdot M \qquad ( 3 )$$

$$\begin{matrix}{y}_{t 1} \\ {y}_{t 2} \\ {y}_{t 3} \\ … \\ {y}_{tn}\end{matrix} = [ \begin{matrix}{T}_{1 t 1} & {T}_{2 t 1} & {T}_{3 t 1} & … & {T}_{28 t 1} \\ {T}_{1 t 2} & {T}_{2 t 2} & {T}_{3 t 2} & … & {T}_{28 t 2} \\ {T}_{1 t 3} & {T}_{2 t} & {T}_{3 t 3} & … & {T}_{28 t 3} \\ … & … & … & … & … \\ {T}_{1 t n} & {T}_{2 t n} & {T}_{3 t n} & … & {T}_{28 tn}\end{matrix} ] \cdot [ \begin{matrix}{M}_{1} \\ {M}_{2} \\ {M}_{3} \\ … \\ {M}_{n}\end{matrix} ] \qquad ( 4 )$$

In an example, the optical measurement may indicate an increased overlay contribution, wherein a thermal problem is suspected on account of the results of the temperature measurements. This suspicion can be confirmed or disproved in model-based fashion with the aid of the measured temperatures by using equation (3). In the case of a confirmation, the system of equations (1) with all available measured information is then used to locate the origin of the problem.

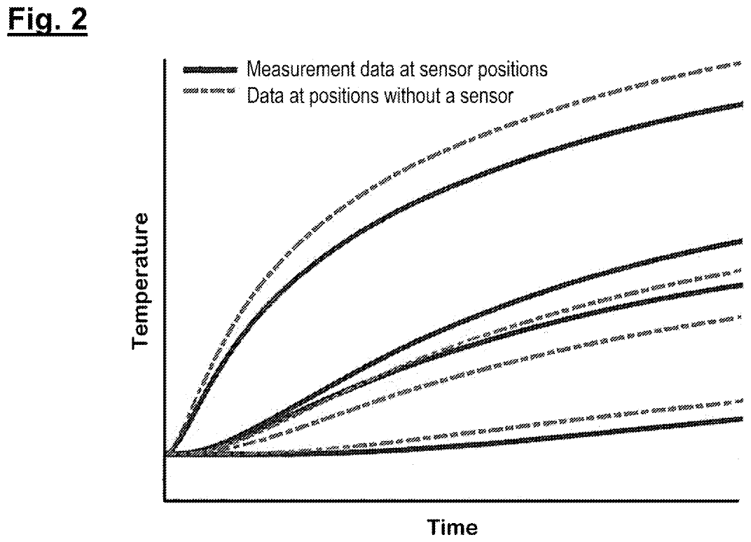

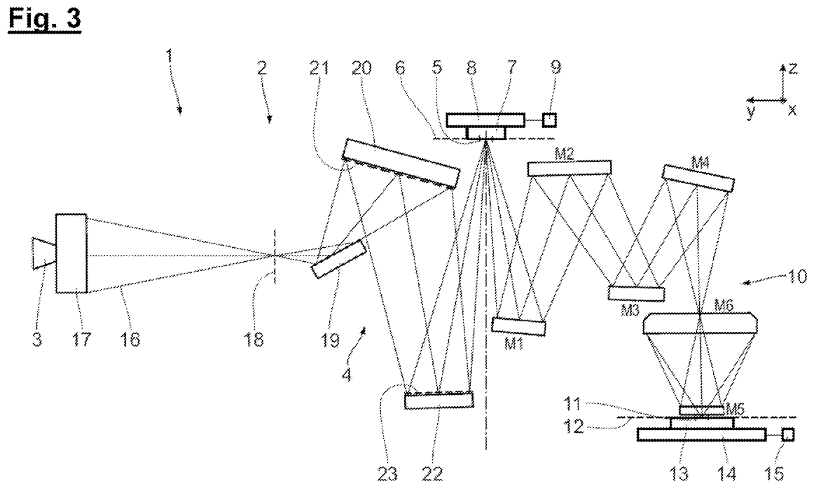

FIG. 3 shows a schematic illustration of a projection exposure apparatus 1 which is designed for operation in the EUV range and in which the disclosure is able to be realized in an exemplary manner. The description of the basic setup of the projection exposure apparatus 1 and its components should not be regarded as limiting here.

One design of an illumination system 2 of the projection exposure apparatus 1 has, in addition to a light source or radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

Here, a reticle 7 arranged in the object field 5 is exposed. The reticle 7 is held by a reticle holder 8. The reticle holder 8 is displaceable, for example in a scanning direction, by way of a reticle displacement drive 9. For explanatory purposes, a Cartesian xyz-coordinate system is depicted in FIG. 1. The x-direction runs perpendicular to the plane of the drawing. The y-direction runs horizontally, and the z-direction runs vertically. The scanning direction runs in the y-direction in FIG. 1. The z-direction runs perpendicular to the object plane 6.

The projection lens 10 serves for imaging the object field 5 into an image field 11 in an image plane 12. A structure on the reticle 7 is imaged onto a light-sensitive layer of a wafer 13 arranged in the region of the image field 11 in the image plane 12. The wafer 13 is held by a wafer holder 14. The wafer holder 14 is displaceable, for example in the y-direction, by way of a wafer displacement drive 15. The displacement on the one hand of the reticle 7 by way of the reticle displacement drive 9 and on the other hand of the wafer 13 by way of the wafer displacement drive 15 may take place in such a way as to be synchronized with one another.

The radiation source 3 is an EUV radiation source. The radiation source 3 for example emits EUV radiation, which is also referred to below as used radiation or illumination radiation. For example, the used radiation has a wavelength in the range between 5 nm and 30 nm. The radiation source 3 can be for example a plasma source, a synchrotron-based radiation source or a free electron laser (FEL). The illumination radiation 16 emanating from the radiation source 3 is focused by a collector 17 and propagates through an intermediate focus in an intermediate focal plane 18 into the illumination optical unit 4. The illumination optical unit 4 comprises a deflection mirror 19 and, arranged downstream thereof in the beam path, a first facet mirror 20 (having schematically indicated facets 21) and a second facet mirror 22 (having schematically indicated facets 23).

The projection lens 10 comprises a plurality of mirrors Mi (i=1, 2, . . . ), which are consecutively numbered according to their arrangement in the beam path of the projection exposure apparatus 1. In the example illustrated in FIG. 1, the projection lens 10 comprises six mirrors M1 to M6. Alternatives with four, eight, ten, twelve or any other number of mirrors Mi are likewise possible. The penultimate mirror M5 and the last mirror M6 each have a through opening for the illumination radiation 16. The projection lens 10 is a doubly obscured optical unit. The projection lens 10 has an image-side numerical aperture that is greater than 0.5 and may also be greater than 0.6, and may be for example 0.7 or 0.75.

Even though the disclosure has been described on the basis of specific embodiments, numerous variations and alternative embodiments will be apparent to a person skilled in the art, for example through combination and/or exchange of features of individual embodiments. Accordingly, it goes without saying for the person skilled in the art that such variations and alternative embodiments are concomitantly encompassed by the present disclosure, and the scope of the disclosure is restricted only within the meaning of the appended claims and the equivalents thereof.

1. A method, comprising:
a) measuring, with sensor assistance, values of at least one physical variable at a plurality of different sensor positions within an optical system;
b) using the measured values to perform a model-based determination of at least one parameter at further positions of the optical system, none of which correspond to a sensor position; and
c) using the model-based determination to diagnose an existing or expected malfunction of the optical system.

2. The method of claim 1, wherein the at least one physical variable in a) comprises temperature.

3. The method of claim 1, wherein the at least one physical variable in a) comprises a wavefront provided by the optical system in a plane.

4. The method of claim 1, wherein the at least one parameter in b) comprises a heat load.

5. The method of claim 1, wherein each of the further positions, none of which correspond to a sensor position, is at a component of the optical system.

6. The method of claim 1, comprising using the model-based determination to automatically plan a countermeasure to remedy or avoid the malfunction.

7. The method of claim 6, comprising implementing the automatic planning based on an assessment of a relevance of the malfunction.

8. The method of claim 1, wherein the optical system is a portion of a microlithographic projection exposure apparatus.

9. The method of claim 8, wherein the sensors are disposed on a sensor frame of the microlithographic projection exposure apparatus.

10. The method of claim 8, wherein the further positions, none of which correspond to a sensor position, are disposed on a force frame of the microlithographic projection exposure apparatus.

11. The method of claim 8, wherein:
the microlithographic projection exposure apparatus comprises a sensor frame and a force frame;
the sensors are disposed on the sensor frame; and
the further positions, none of which correspond to a sensor position, are disposed on the force frame of the microlithographic projection exposure apparatus.

12. The method of claim 11, wherein the optical system is a projection lens of the microlithographic projection exposure apparatus.

13. The method of claim 8, wherein the optical system is a projection lens of the microlithographic projection exposure apparatus.

14. The method of claim 1, wherein the at least one physical variable in a) comprises the temperature, and the at least one parameter in b) comprises a heat load.

15. The method of claim 14, wherein each of the further positions, none of which correspond to a sensor position, is at a component of the optical system.

16. The method of claim 14, comprising using the model-based determination to automatically plan a countermeasure to remedy or avoid the malfunction.

17. The method of claim 1, wherein the at least one physical variable in a) comprises a wavefront provided by the optical system in a plane, and the at least one parameter in b) comprises a heat load.

18. The method of claim 17, wherein each of the further positions, none of which correspond to a sensor position, is at a component of the optical system.

19. The method of claim 17, comprising using the model-based determination to automatically plan a countermeasure to remedy or avoid the malfunction.

20. The method of claim 1, wherein:
the at least one physical variable in a) comprises at least one member selected from the group consisting of temperature and a wavefront provided by the optical system in a plane;
the at least one parameter in b) comprises a heat load;
each of the further positions, none of which correspond to a sensor position, is at a component of the optical system;
the method comprises using the model-based determination to automatically plan a countermeasure to remedy or avoid the malfunction;
the optical system is a microlithographic projection exposure apparatus;
the microlithographic projection exposure apparatus comprises a sensor frame and a force frame;
the sensors are disposed on the sensor frame; and
the further positions, none of which correspond to a sensor position, are disposed on the force frame of the microlithographic projection exposure apparatus.
